(19) United States
(12) Patent Application Publication
(10) Pub. No.: US 2019/0212656 A1
(43) Pub. Date: Jul. 11, 2019

(54) PVD Films For EUV Lithography

(71) Applicants: Applied Materials, Inc., Santa Clara, CA (US); International Business Machines Corporation, Armonk, NY (US)

(72) Inventors: Huixiong Dai, San Jose, CA (US); Weimin Zeng, San Jose, CA (US); Daniel Lee Diehl, Mihama-ku Chiba (JP); Yong Cao, San Jose, CA (US); Hsiang Ning Wu, Santa Clara, CA (US); Khoi Phan, San Jose, CA (US); Christopher S. Ngai, Burlingame, CA (US); Mingwei Zhu, San Jose, CA (US); Michael Stolfi, Clifton Park, NY (US); Nelson M. Felix, Slingerlands, NY (US); Ekmini Anuja DeSilva, Slingerlands, NY (US); Xianmin Tang, San Jose, CA (US)

(21) Appl. No.: 16/244,381

(22) Filed: Jan. 10, 2019

Related U.S. Application Data
(60) Provisional application No. 62/615,765, filed on Jan. 10, 2018.

(51) Int. Cl. G03F 7/20; G03F 7/00

(52) U.S. Cl. CPC G03F 7/70058; G03F 7/70033; G03F 7/0035; G03F 7/2022

(57) ABSTRACT

Methods for depositing an EUV hardmask film on a substrate by physical vapor deposition which allow for reduced EUV dose. Certain embodiments relate to metal oxide hardmasks which require smaller amounts of EUV energy for processing and allow for higher throughput. A silicon or metal target can be sputtered onto a substrate in the presence of an oxygen and or doping gas containing plasma.

### CROSS-REFERENCE TO RELATED APPLICATIONS

This application claims priority to U.S. Provisional Application No. 62/615,765, filed Jan. 10, 2018, the entire disclosure of which is hereby incorporated by reference herein.

### TECHNICAL FIELD

The present disclosure relates generally to methods of forming EUV hardmasks. In particular, the disclosure relates to methods to form EUV hardmasks comprising high Z metal oxides or high Z doped amorphous silicon.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The multilevel interconnects that lie at the heart of this technology require precise imaging and placement of high aspect ratio features. Reliable formation of these interconnects is needed to further increases in device and interconnect density. One process used to form various interconnect and other semiconductor features uses EUV (extreme ultraviolet) lithography. Conventional EUV patterning uses a multilayer stack in which a photoresist is patterned on top of a hardmask. Common hardmask materials are spin-on silicon anti-reflective coating (SiARC) and a deposited silicon oxynitride (SiON). The SiARC incorporates organic content to a silicon backbone, maintaining sufficient etch selectivity to the photoresist and underlying stack. Scaling the thickness of the SiARC backbone can be challenging and spin coating limits the minimum thickness that can be achieved without too many defects. The SiON hardmask uses an organic adhesion layer (OAL) for improved resist adhesion. The OAL prevents poisoning from nitrogen and is able to be reworked.

Several metal oxide materials have been tested as EUV hardmasks (HM). The metal oxide films, including films with high EUV absorption elements were stoichiometric and not conductive.

Amorphous silicon (a-Si) is used as a hardmask or mandrel for many patterning applications and has excellent dimension uniformity (CDU), line-edge roughness (LER), line-width roughness (LWR) and dose control. However, the high deposition temperatures of most chemical vapor deposition (CVD) a-Si processes, a-Si has not been used as a hardmask for resist pattern transfer. Amorphous silicon has the highest content of silicon for a hardmask film and might provide good selectivity to organic films.

However, processing of EUV lithography generally takes a significant amount of exposure time and requires large amounts of energy. To increase processing throughputs, there is a need in the art for new photoresist materials and processing methods that allow for decreased dose time and/or lower dose energies.

### SUMMARY

One or more embodiments of the disclosure are directed to methods of forming a hardmask. The methods comprise placing a substrate on a substrate support within a processing volume of a deposition chamber opposite a target that comprises a metal-containing material. Material from the target is sputtered onto the substrate. The substrate is exposed to a sputter gas within the processing volume to form a metal-rich metal oxide film. The sputter gas comprises an oxygen-containing gas and an inert gas.

Additional embodiments of the disclosure are directed to methods of forming a hardmask. A substrate is placed on a substrate support within a processing volume of a deposition chamber opposite a target. The target consists essentially of tin metal, and the substrate is maintained at about 25° C. Material from the target is sputtered onto the substrate. The substrate is simultaneously exposed to a sputter gas comprising argon and oxygen in a ratio greater than or equal to 1:1 to form a hardmask. The hardmask has a ratio of tin atoms to oxygen atoms of greater than 1:1.

Further embodiments are directed to methods of forming a hardmask. A substrate is placed on a substrate support within a processing volume of a deposition chamber opposite a target. The target comprises at least one metal-containing material or silicon. Material from the target is sputtered onto the substrate. The substrate is exposed to a doping gas comprising one or more of oxygen, ozone, or xenon.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

EUV lithography generally takes a significant amount of exposure time and uses large amounts of energy. Some embodiments of the disclosure advantageously provide methods and materials to reduce the energy and/or exposure time required for EUV lithography. One or more embodiments of the disclosure provide methods for producing materials which provide ample secondary electrons when excited by EUV radiation. Some embodiments of the disclosure provide methods for producing materials that have better conductivity. Fully stoichiometric metal oxides may not yield as many electrons as metal rich oxides or conducting oxides. Metal rich oxides with high Z properties and lower resistance are considered for EUV HM. Elements including xenon (Xe), tin (Sn), indium (In), gallium (Ga), zinc (Zn), tellurium (Te), antimony (Sb), and nickel (Ni) are high EUV absorption materials commonly used in the semiconductor industry. In some embodiments, the target comprises silicon that is infused or doped with a high EUV absorption material. For example, some embodiments use tin infused silicon as a target. In some embodiments, the target comprises a high EUV absorption material that is infused or doped with silicon. For example, some embodiments use silicon doped tin as a target. In some embodiments, materials such as SnOx, InOx, TiOx, AlOx, TaOx, NiOx, GST and IGZO are utilized as EUV HM. For example, some embodiments use Indium Tin Oxide (ITO) as a EUV HM. Without being bound by theory, it is believed that the high EUV absorption by both indium and tin allow for creation of a sufficient supply of secondary electrons when excited by EUV. In some embodiments, ITO films have the ability to readily conduct electrons to the resist surface.

In some embodiments, adjusting the composition ratios of the ITO film are modified to increase film density. In some embodiments, composition ratios varying from 3% tin to 10% tin may provide a dense ITO film with low particles and a small amount of the high resistance In₄Sn₃O₁₂ phase. In some embodiments, ITO films are transparent, allowing for the ability to see alignment marks in the visible spectrum.

One or more embodiments of the disclosure are directed to methods to develop new physical vapor deposited films or hardmasks for next generation lithography applications. These films allow for a reduction in the amount of EUV exposure as measured in exposure time and/or exposure energy. Some embodiments provide hardmasks which allow for a dosage reduction of about 5 to about 15 percent. Some embodiments provide hardmasks which allow for a dosage reduction of about 5 to about 20 percent. The dose is the amount of energy that is used to print the mask on the wafer. The reduced exposure and/or dosage advantageously provides for a higher processing throughput.

Embodiments of the disclosure provide methods of depositing a film using a sputtering process known to the skilled artisan. Briefly, a sputtering process occurs in a vacuum chamber (also referred to as a deposition chamber) at low pressures. A gas is introduced to the reaction space of the vacuum chamber and a plasma is ignited (e.g., using RF power). The energized gas causing atoms from a target to be ejected. These atoms form the hardmask film on the substrate.

One or more embodiments of the disclosure are directed methods of forming metal-rich metal oxide films by physical vapor deposition. A substrate is placed on a substrate support within a processing volume of a deposition chamber. The substrate support including the substrate is positioned opposite a target so that the surface of the substrate faces the target.

The substrate is exposed to a sputter gas within the processing volume. As used in this manner, the term “sputter gas” means one or more gaseous species that can be ignited into a plasma and/or sputter material from the target. In some embodiments, the sputter gas comprises an oxygen-containing gas and an inert gas. The oxygen-containing gas of some embodiments comprises one or more of oxygen (O₂), ozone (O₃) or water (H₂O).

The sputter gas composition can remain constant throughout processing or can be changed during processing. In some embodiments, the sputter gas composition remains substantially the same throughout the sputter process. As used in this manner, the term “substantially the same” means that the relative composition of each component of the sputter gas does not change by more than 5% (by weight) through sputtering. In some embodiments, the composition of the sputter gas is changed during processing to control the amount of oxygen in the resulting hardmask film. In some embodiments, the sputter gas has a constant flow of inert gas and the oxygen-containing gas is pulsed into the process chamber. The duration, spacing and concentration/flow rate of the pulses can be controlled to change the composition of the hardmask film.

In some embodiments, material is sputtered onto the substrate using a sputter gas consisting essentially of an inert gas. As used in this manner, the term “consisting essentially of” means that the composition of the sputter gas is greater than or equal to about 95%, 98% or 99% of the stated species on a molar basis.

After sputtering, the material deposited on the substrate can be exposed to the oxygen-containing gas or a plasma containing the oxygen-containing gas. In this regard, the sputtering and oxygenating processes are described as occurring sequentially. Those skilled in the art will recognize that if the processes occur sequentially, either sputtering or exposure to the sputter gas may occur first.

The target can be made of silicon and/or any suitable metal-containing material. Non-limiting examples of suitable metal-containing materials include metals, metal alloys, metal oxides, metal nitrides, metal borides metal carbides, metal silicides and combinations thereof. In some embodiments, the metal-containing material comprises one or more of Sn, In, Ga, Zn, Te, Sb, Ni, Ti, Al, or Ta. In some embodiments, the metal-containing material consists essentially of one or more of Sn, In, Ga, Zn, Te, Sb, Ni, Ti, Al, or Ta. In some embodiments, the metal-containing material consists essentially of tin metal. In this regard, “consists essentially of” means that the target material is greater than 98%, 99% or 99.5% of the stated material(s). In some embodiments, the target material comprises or consists essentially of a combination of indium and tin. In some embodiments, the target material comprises or consists essentially of a combination of indium, tin and oxygen. In some embodiments, the target material comprises or consists essentially of a combination of silicon and tin. In some embodiments, the target material consists essentially of tin doped with less than 5%, less than 2% or less than 1% silicon on an atomic basis. In some embodiments, the metal-containing material is doped with silicon. In some embodiments, the target comprises a metal-containing material and silicon in a range of about 1 atomic percent to about 5 atomic percent. In some embodiments, the target comprises or consists essentially of a metal or metal alloy. Stated differently, in some embodiments the target comprises less than or equal to about 5%, 2%, 1% or 0.5% non-metal atoms, on an atomic basis.

The oxygen-containing gas can be any suitable reactant for forming a metal oxide hardmask or for doping the hardmask with oxygen. In some embodiments, the oxygen-containing gas comprises one or more of oxygen, ozone, or water. In some embodiments, the oxygen-containing gas consists essentially of oxygen. In some embodiments, the oxygen-containing gas consists essentially of ozone. In some embodiments, the oxygen-containing gas consists essentially of water. In this regard, “consists essentially of” means that the oxygen-containing gas is greater than 98%, 99% or 99.5% of the stated reactant.

In some embodiments, the inert gas is flowed into the processing volume and a plasma is ignited from the inert gas. The inert gas used to ignite the plasma is also referred to as a plasma excitation gas. In some embodiments, the inert gas comprises one or more of Ar, He, Ne, Kr or Xe. In some embodiments, the inert gas consists essentially of argon. In some embodiments, the inert gas consists essentially of xenon. In this regard, “consists essentially of” means that the inert gas is greater than 98%, 99% or 99.5% of the stated gas. The inert gas can be a carrier gas, diluent gas, inert gas and/or plasma excitation gas. In some embodiments, the oxygen-containing gas and the inert gas are mixed prior to being flowed into the processing volume. In some embodiments, the inert gas and the oxygen-containing gas are not mixed prior to being flowed into the processing volume. The inert gas and the oxygen-containing gas may be delivered to the processing volume separately. In some embodiments, the sputter gas consists essentially of an inert gas.

The sputter gas comprising the oxygen-containing gas and the inert gas can be delivered at any suitable flowrate. The flowrate of the sputter gas or the individual components of the sputter gas (i.e., the oxygen-containing gas and the inert gas) can each be controlled. In some embodiments, the flow rate of the oxygen-containing gas and the inert gas are less than or equal to about 200 sccm, about 150 sccm, about 100 sccm, about 80 sccm, about 60 sccm, about 50 sccm, about 40 sccm, about 30 sccm, about 25 sccm, about 20 sccm, about 15 sccm, or about 10 sccm. In some embodiments, the flow rate of the inert gas is about 100 sccm. In some embodiments, the flow rate of the oxygen-containing gas is about 100 sccm. In some embodiments, the inert gas is flowed at a flow rate less than the oxygen-containing gas. In some embodiments, the inert gas is flowed at a flow rate about equal to the oxygen-containing gas. In some embodiments, the inert gas is flowed at a flow rate greater than the oxygen-containing gas. In some embodiments, the ratio of the flow rate of the inert gas to the flow rate of the oxygen-containing gas is in the range of about 30:1 to about 1:2, about 30:1 to about 1:1, about 30:1 to about 5:1, about 30:1 to about 10:1, about 25:1 to about 15:1, or about 30:1 to about 15:1. In some embodiments, the ratio is about 30:1, about 20:1, about 15:1, about 10:1, about 8:1, about 6:1, about 5:1, about 4:1, about 3:1, about 2:1, about 1:1, or about 1:2. In some embodiments, the ratio is greater than or equal to about 1:1.

In some embodiments, the substrate is maintained at a set temperature during sputtering. In some embodiments, the substrate is maintained at a temperature less than or equal to about 50° C., less than or equal to about 25° C., less than or equal to about 20° C., less than or equal to about 15° C., less than or equal to about 10° C., less than or equal to about 5° C., less than or equal to about 0° C., or less than or equal to about −10° C. In some embodiments, the substrate is maintained at a temperature of about 25° C. In some embodiments, the substrate is maintained at a temperature in the range of about −25° C. to about 50° C.

In some embodiments, the substrate is maintained at a temperature in the range of about −25° C. to about 400° C., or in the range of about −20° C. to about 400° C., or in the range of about 0° C. to about 350° C., or in the range of about 25° C. to about 300° C., or in the range of about 100° C. to about 250° C., or in the range of about 150° C. to about 250° C. In some embodiments, the substrate is maintained at a temperature of about 200° C.

In some embodiments, the hardmask comprises a metal oxide film. In some embodiments, the metal oxide film contains a non-stoichiometric ratio of metal and oxygen. In some embodiments, the metal oxide film is a metal-rich film. A metal-rich film contains a higher ratio of metal atoms to oxygen atoms than for a stoichiometric metal oxide film. In some embodiments, the stoichiometric metal oxide may be characterized as MₓO_{y}, where M is one or more metal. In some embodiments, the ratio of metal to oxygen in the hardmask is greater than x:y, greater than 1.5x:y or greater than 2x:y. For example, a stoichiometric tin oxide (SnO₂) would have a tin:oxygen ratio of 1:2. A metal-rich tin oxide film might have a tin:oxygen ratio greater than or equal to about 1.1:2, 1.5:2, 1.8:2, 2:2 (i.e., 1:1) or higher.

In some embodiments, the metal oxide film is a tin oxide film. In some embodiments, the tin oxide film has a ratio of oxygen atoms to tin atoms of less than 2:1. In some embodiments, the ratio of tin atoms to oxygen atoms is equal to about 1:1. In some embodiments, the ratio of tin atoms to oxygen atoms is greater than 1:1. This may also be referred to as a metal-rich metal oxide film, or an oxygen-deficient metal oxide film.

In some embodiments, the metal oxide film is a tantalum oxide film. In some embodiments, the tantalum oxide film has a ratio of oxygen atoms to tantalum atoms of less than 5:2. In some embodiments, the ratio of tantalum atoms to oxygen atoms is equal to about 2:1, equal to about 3:2, or equal to about 1:1. In some embodiments, the ratio of tantalum atoms to oxygen atoms is greater than 1:1.

In some embodiments, the metal oxide film is a mixed metal oxide film, for example, an indium tin oxide (ITO) film. ITO films are optically transparent and it has been found the use of ITO as a hardmask can allows viewing alignment marks in the visible spectrum. In embodiments with a mixed metal oxide film, a metal-rich film is defined as a film that has at least one of the metals in greater than a stoichiometric amount relative to oxygen.

In some embodiments, the density of the hardmask is controlled by adjusting the amount of oxygen within the hardmask. In some embodiments, the hardmask has a density of less than 7.0 g/cm³. In some embodiments, the hardmask has a density in the range of about 5.0 g/cm³ to about 6.5 g/cm³.

The thickness of the hardmask can be any suitable thickness. In some embodiments, the hardmask has a thickness of about 10 nm. In some embodiments, the hardmask has a thickness of greater than 3 nm, greater than 5 nm, greater than 7 nm, greater than 10 nm, or greater than 15 nm. In some embodiments, the hardmask has a thickness of less than 20 nm, less than 15 nm, less than 10 nm, less than 7 nm, or less than 5 nm. In some embodiments, the hardmask has a thickness in the range of about 3 nm to about 20 nm.

In some embodiments, the roughness (Ra) of the hardmask is controlled by adjusting the amount of oxygen within the hardmask. In some embodiments, the roughness of the hardmask is less than or equal to about 0.7 nm, less than or equal to about 0.5 nm, less than or equal to about 0.3 nm, less than or equal to about 0.2 nm, less than or equal to about 0.15 nm, or less than or equal to about 0.1 nm.

### EXAMPLES

A PVD of a metal-rich metal oxide was performed. A pure tin metal target was used. The substrate was maintained at room temperature. Sputtering was performed through the use of a pulsed DC at 100 kHz, and 40% duty cycle. A sputter gas was flowed into the chamber during sputtering. The sputter gas comprised both argon and oxygen. The argon component of the sputter gas was flowed at 100 sccm.

Example 1: The oxygen component of the sputter gas was flowed at 20 sccm. The ratio of argon:oxygen within the sputter gas was 5:1. The deposited film was a metal-rich tin oxide film with a ratio of tin:oxygen atoms of about 1:1.

Example 2: The oxygen component of the sputter gas was flowed at 10 sccm. The ratio of argon:oxygen within the sputter gas was 10:1. The deposited film was a metal-rich tin oxide film with a ratio of tin:oxygen atoms of about 3:2.

One or more embodiments of the disclosure are directed to methods of depositing doped silicon or metal hardmasks. For example, xenon doped silicon has been found to provide a film that uses lower EUV dosages than metal oxides with higher EUV absorption.

The doping element can be any suitable element that is highly absorbant of EUV radiation. This is also referred to as a high Z material. Suitable elements include, but are not limited to, Sn, In, Ga, Zn, Te, Sb, Ni, Ti, Al, Ta, and xenon (Xe). In some embodiments, a xenon-doped hardmask is formed. Xenon doping can occur with formation of a metal oxide—as described with respect to the formation of metal-rich metal oxides—by co-flowing xenon with the sputter gas, or using xenon as the inert gas of the sputter gas.

In some embodiments, the hardmask film comprises an amorphous silicon film doped with a highly EUV absorbing element. In some embodiments, the highly EUV absorbing element comprises or consists essentially of xenon. As used in this manner, the term “consists essentially of” the dopant is greater than or equal to about 95%, 98% or 99% of the stated dopant on an atomic basis.

In some embodiments, xenon, boron or any of the other high Z materials are doped into the silicon target used for deposition or into other targets for the aforementioned materials. In some embodiments, one material is used as the bulk of the EUV HM and then the surface HM is treated with a high Z material. In some embodiments, the surface is treated to be more electrically conductive.

The dopant can be introduced into the hardmask film in different ways. In some embodiments, the inert gas of the sputter gas comprises or consists essentially of the doping gas. The doping gas of some embodiments is any suitable gas or mixture of gases for doping the hardmask with xenon.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming a hardmask, the method comprising:
placing a substrate on a substrate support within a processing volume opposite a target in a deposition chamber, the target comprising a metal-containing material or Si;
exposing the substrate and target to a sputter gas within the processing volume to form a metal-rich metal oxide film, the sputter gas comprising an oxygen-containing gas and an inert gas; and
sputtering the metal-containing material or Si onto the substrate.

2. The method of claim 1, wherein oxygenating and sputtering occur sequentially.

3. The method of claim 1, wherein sputtering the metal-containing material and exposing the substrate to a sputter gas occur together.

4. The method of claim 1, wherein the metal-containing material comprises one or more of Sn, In, Ga, Zn, Te, Sb, Ni, Ti, Al, or Ta.

5. The method of claim 4, wherein the target comprises a metal containing material doped with silicon in a range of about 1 atomic percent to about 5 atomic percent.

6. The method of claim 4, wherein the metal-containing material consists essentially of tin metal.

7. The method of claim 1, wherein the oxygen-containing gas comprises one or more of oxygen, ozone, or water.

8. The method of claim 1, wherein the inert gas comprises one or more of Ar, He, Ne, Kr or Xe.

9. The method of claim 1, wherein a ratio of a flow rate of the inert gas to a flow rate of the oxygen-containing gas is in a range of about 30:1 to about 1:2.

10. The method of claim 1, wherein the substrate is maintained at a temperature in a range of about −20° C. to about 400° C.

11. The method of claim 1, wherein the metal-rich metal oxide film formed consists essentially of tin and oxygen atoms.

12. The method of claim 11, wherein a ratio of oxygen atoms to tin atoms is less than 1.5:1.

13. The method of claim 1, wherein the metal-rich metal oxide film is formed to a thickness in the range of about 3 nm to about 20 nm.

14. A method of forming a hardmask, the method comprising:
placing a substrate on a substrate support within a processing volume of a deposition chamber opposite a target, the target comprising at least one metal-containing material or silicon;
exposing the substrate and target to a doping gas comprising one or more of oxygen, ozone, xenon to incorporate elements of the doping gas into the target; and
sputtering material from the target onto the substrate to form a hardmask.

15. The method of claim 14, wherein sputtering material from the target occurs with a plasma containing the doping gas.

16. The method of claim 14, wherein the target comprises silicon and the doping gas consists essentially of xenon.

17. The method of claim 16, wherein sputtering material from the target occurs with a plasma containing the doping gas.

18. The method of claim 14, wherein the target comprises one or more of Si, Sn, In, Ga, Zn, Te, Sb, Ni, Ti, Al, or Ta.

19. The method of claim 18, wherein the target consists essentially of indium and tin and sputtering material from the target occurs with a plasma containing oxygen and xenon to form a hardmask comprising a xenon-doped metal-rich indium tin oxide.

20. The method of claim 14, wherein the target comprises tin doped with silicon in a range of about 1 atomic percent to about 5 atomic percent.
